(19) United States
(12) Patent Application Publication
(10) Pub. No.: US 2011/0018057 A1
(43) Pub. Date: Jan. 27, 2011

(54) SEMICONDUCTOR MEMORY DEVICE AND METHOD FOR FABRICATING THE SAME

(75) Inventor: Jong Il Kim, Icheon-si (KR)

Correspondence Address: AMPACC Law Group, PLLC, 6100 219th Street SW, Suite 580, Mountlake Terrace, WA, 98043, US

(73) Assignee: Hynix Semiconductor Inc., Icheon-si (KR)

(21) Appl. No.: 12/650,097

(22) Filed: Dec. 30, 2009

(30) Foreign Application Priority Data
Jul. 24, 2009 (KR) 10-2009-0067919

(51) Int. Cl. H01L 29/78; H01L 21/336

(52) U.S. Cl. 257/330; 438/270; 257/E29.262; 257/E21.41

(57) ABSTRACT

A manufacturing method of a semiconductor device comprises forming a semiconductor substrate including an active region and an element isolation film, forming a first recess on the semiconductor substrate, forming an oxide film on a sidewall of the first recess, forming a second recess by etching a lower part of the first recess, and forming a gate in a lower part of the second recess.

### CROSS-REFERENCE TO RELATED APPLICATION

The priority based on Korean patent application No. 10-2009-0067919 filed on Jul. 24, 2009, the disclosure of which is hereby incorporated in its entirety by reference, is claimed.

### BACKGROUND OF THE INVENTION

The present invention relates to a fabricating method of a high integrated semiconductor memory device, and more specifically, to a stably operable semiconductor memory device having a buried gate structure and a fabricating method of the same.

A semiconductor memory device includes a plurality of unit cells, each of which includes a capacitor and a transistor. The capacitor is used for temporarily storing data, and the transistor is used for transferring the data between a bit line and the capacitor in response to a control signal (word line) using properties of a semiconductor, i.e., a change of an electric conductivity in a channel region according to conditions such as an electric field. The transistor has three regions, i.e., a gate, a source and a drain. According to a control signal inputted to the gate, an electric charge moves through the channel region between the source and the drain. The movement of the electric charge results in transferring the data between the source and the drain.

In the case of fabricating a conventional transistor on a semiconductor substrate, the gate is formed on the semiconductor substrate and the source and the drain are formed by doping both sides of the gate with impurities. As a data storing capacity and an integration density of the semiconductor memory device are increased, the size of each unit cell needs to decrease. That is, the design rule for a capacitor and a transistor included in a unit cell needs to be reduced, and the channel length of a cell transistor has been shortened accordingly. As a result, the short channel effect, the drain induced barrier lowering (DIBL) and other undesirable phenomena associated with small sized devices were observed in the conventional transistor.

The short channel can be compensated by a number of different ways. One way is to increase the doping concentration for the channel. Another is to use a different gate material, e.g., silicon-germanium alloy, from conventional silicon.

However, as the design rule reaches below 100 nm, the method of increasing the channel doping concentration results in another problem, i.e., the electric field at a storage node (SN) junction is increased. This electric field increase degrades refresh properties of the semiconductor memory device. In order to overcome this issue, a cell transistor having a 3-dimensional channel structure, where a long length of the channel is secured in vertical direction, has been introduced in order to maintain the channel length sufficiently long as the devices are being scaled down. Accordingly, even though channel width in a horizontal direction is short, the channel length in a vertical direction can be kept sufficient long.

Meanwhile, as the integration for a semiconductor memory device increases, the distance between a word line and a bit line coupled to the cell transistor becomes shorter. Since parasitic capacitance generated due to the short distance between the word line and the bit line is increased, an operational margin for a sense amplifier for amplifying data transferred through the bit line also decreases. Accordingly, the operational stability of the semiconductor memory device may be degraded.

One method for reducing parasitic capacitance between the word line and the bit line is the use of, a buried gate structure, where the word line, i.e., the gate of the cell transistor, is formed within one or more recesses (or trenches) formed in the substrate. According to the buried gate structure, conductive material is formed in the recess formed in the semiconductor substrate, and an upper part of the conductive material is covered with an insulating film in order to bury the gate within the semiconductor substrate so that the gate can be more securely isolated from the bit line formed on the semiconductor substrate where the source and the drain are formed.

FIGS. 1a to 1e are cross-sectional views for explaining a fabricating method of a semiconductor memory device having a conventional buried gate structure.

Referring to FIG. 1a, a pad oxide film 101 serving as an insulating film and a nitride film 102 are formed on a semiconductor substrate 100, an element isolation film 103 which defines an active region in the semiconductor substrate 100 is formed by using a shallow trench isolation (STI) technique.

Referring to FIG. 1b, recesses 104 are formed both in the active region and in the element isolation film 103 through an etching process using a recess gate mask. For example, two recesses 104 are formed in a single active region, and the single recess 104 is formed within the element isolation film 103.

As shown in FIG. 1c, after a gate oxide film 107 is formed on a surface of the recess 104 by performing a gate oxidation process, a conductive layer 105 is formed over the active region and the element isolation film by filling in the recess 104. Herein, the conductive material can be formed of polysilicon or metal material.

Referring to FIG. 1d, a gate hard mask layer 106 is deposited on the conductive layer 105 over the semiconductor substrate 100.

Thereafter, as shown in FIG. 1e, a recess gate 108 is formed by patterning the gate hard mask layer 106 and the conductive layer 105. On a sidewall of the recess gate 108, a spacer 109 is additionally formed. Although not shown, at both sides of the recess gate 108 in the active region, a storage node contact (not shown) for a connection to a cell capacitor and a bit line contact (not shown) for a connection to a bit line are formed, respectively.

Recently, the integration of the semiconductor memory device has been increased shortening the distance between a word line and a bit line coupled to a cell transistor. Because parasitic capacitance generated due to the short channel has also increased, the operational margin of the sense amplifier has been diminished, degrading the operational stability of the semiconductor memory device. The simplest way to reduce parasitic capacitance is to increase the distance between the recess gate and the contact plug for a word line or a bit line; however, this would result in a larger unit cell size which runs contrary to the goal of providing highly integrated semiconductor devices.

The source and drain regions (not shown) are formed on the both sides of the recess gate 108. If electric charge is stored in the capacitor through a storage-node-contact-junction, the storage-node-contact-junction is formed extending downwards to the semiconductor substrate and reaching to a location deeper than the point an impurity ion may reach by an ion injection process.

As an overlap between the storage node contact region and the gate becomes wider and the electric field on the gate oxide film is increased, a gate-induced-drain-leakage (GIDL) is increased, thus deteriorating the refresh properties of the semiconductor memory device.

### BRIEF SUMMARY OF THE INVENTION

Embodiments of the present invention are directed to a semiconductor memory device and a fabricating method of the same capable of reducing the GIDL occurrence by forming an insulating film between the buried gate and the source and drain regions. The benefits include suppressing the short channel effect and the parasitic capacitance generated in the highly integrated semiconductor device.

In accordance with one embodiment of the present invention, there is provided a manufacturing method of a semiconductor device, comprising forming a semiconductor substrate including an active region and an element isolation film; forming a first recess on the semiconductor substrate; forming an oxide film on a sidewall of the first recess; forming a second recess by etching a lower part of the first recess; and forming a gate in a lower part of the second recess.

Preferably, the manufacturing method further comprises forming a gate insulating film on an inside wall of the second recess before forming the gate.

Preferably, the manufacturing method further comprises forming a source and drain regions on an upper part of the active region, wherein a depth of the source and drain regions is shallower than that of the oxide film.

Preferably, the gate is formed in a depth of about 1500 to 1700 Å within the active region having a thickness of about 700 to 1000 Å.

Preferably, the forming the first recess on the semiconductor substrate includes depositing a hard mask film on the semiconductor substrate; forming a photoresist pattern on the hard mask film; etching the hard mask film exposed by the photoresist pattern; and etching the exposed active region using the etched hard mask film as an etching mask.

Preferably, the forming the oxide film on the sidewall of the first recess includes a dry oxidation for oxidizing the active region exposed by the first recess.

Preferably, the oxide film is formed on the sidewall of the first recess having a thickness of about 100 to 200 Å.

In accordance with another embodiment of the present invention, there is provided a semiconductor device comprising a semiconductor substrate including an active region and an element isolation film; a first recess formed within the active region; an oxide film formed on a sidewall of the first recess; a second recess which is more deeply extended from the first recess; and a gate positioned in a lower part within the second recess.

Preferably, the semiconductor device further comprises a gate insulating film between the second recess and the gate.

Preferably, the semiconductor device further comprises a source and drain regions formed on an upper part of the active region, wherein a depth of the source and drain regions is shallower than that of the oxide film.

Preferably, the oxide film reduces a leakage current by reducing strength of an electric field formed between the gate and the source and drain regions.

Preferably, the gate is formed in a depth of about 1500 to 1700 Å within the active region having a thickness of about 700 to 1000 Å.

Preferably, the element isolation film is formed to a depth of about 3000 Å in the semiconductor substrate.

Preferably, a thickness of the oxide film is about 100 to 200 Å.

### BRIEF DESCRIPTION OF THE DRAWINGS

FIGS. 1a to 1e are cross-sectional views for explaining a fabricating method of a semiconductor memory device having a conventional buried gate structure.

FIGS. 2a to 2e are cross-sectional views for explaining a fabricating method of a semiconductor memory device in accordance with a preferred embodiment of the present invention.

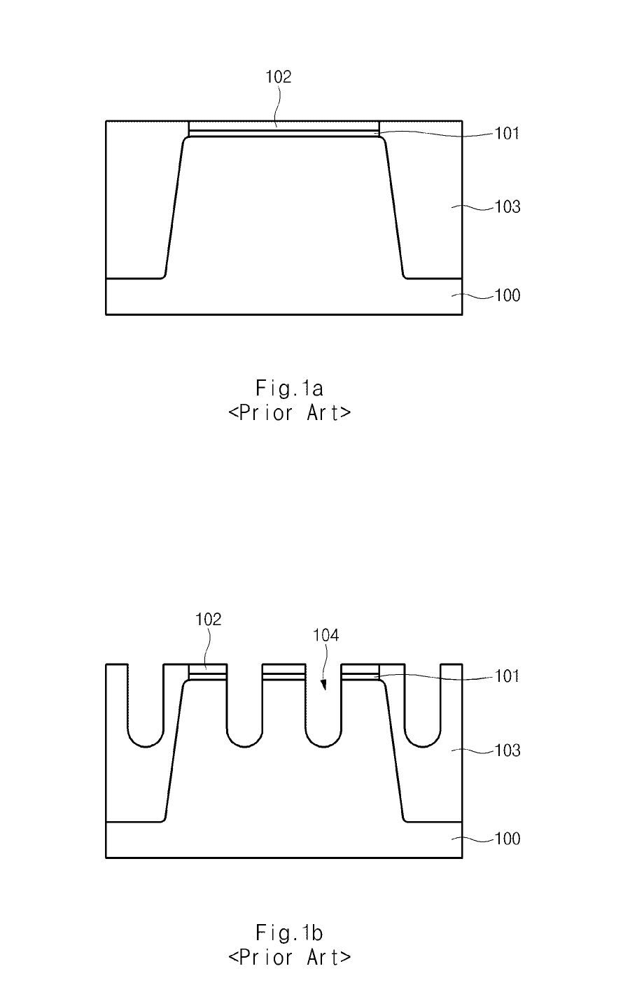

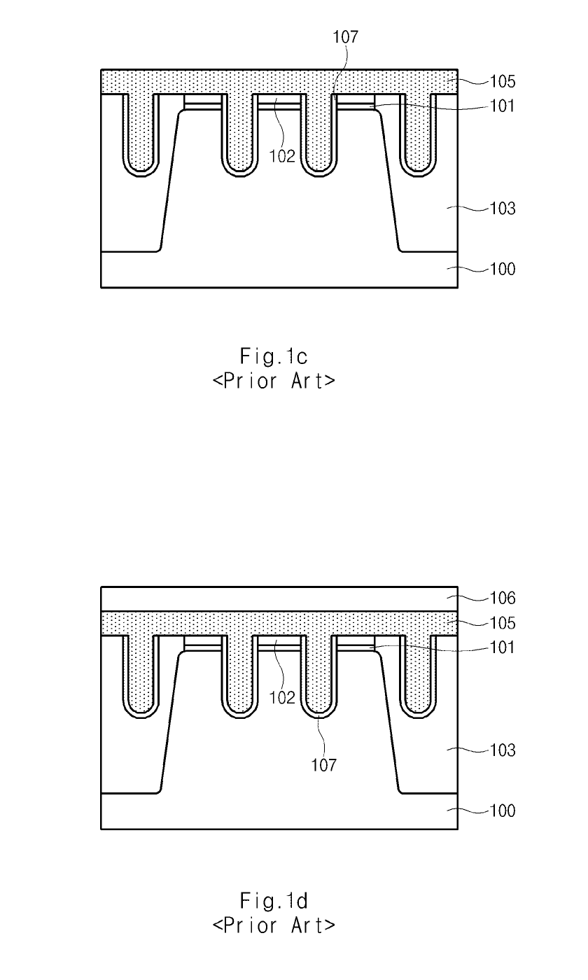

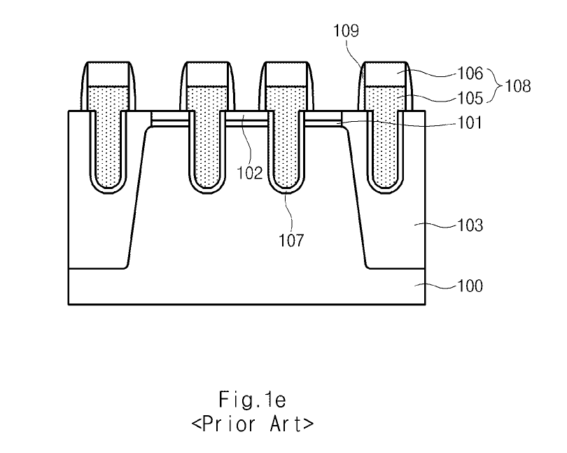

### DESCRIPTION OF EMBODIMENTS

The present invention is directed to a semiconductor device including a buried gate structure. One embodiment of the present invention is directed to lowering parasitic capacitance. Since the buried gate is formed only at a lower part of a recess, a physical distance between a source/drain contact connected to either a source (capacitor) or a drain (bit line) and the buried gate can be increased so that the parasitic capacitance can be greatly reduced. However, a cross section size of the buried gate filling in a lower part of the recess is smaller in comparison with the recess gate filling in the whole recess. Therefore, it is preferable to use metal material instead of polysilicon as a conductive material constituting the buried gate.

Recently, a metal gate has been used instead of N+ poly-gate for forming the buried gate structure; however, a work function of the metal gate is higher than that of the N+ poly-gate so that a stronger electric field is applied to a gate oxide film. As a result, GIDL increases between a buried gate and a source/drain junction region, degrading the refresh properties of the semiconductor device. If a metal film serving as a buried gate is made shallow to reduce GIDL, a channel length is decreased and thus gate resistance is increased. This short channel effect can be compensated by increasing the threshold voltage by increasing impurity dose in the channel region. However, it causes GIDL and aggravates refresh properties of the semiconductor memory device.

Hereinafter, a preferred embodiment of the present invention is described in detail with reference to the accompanying drawings.

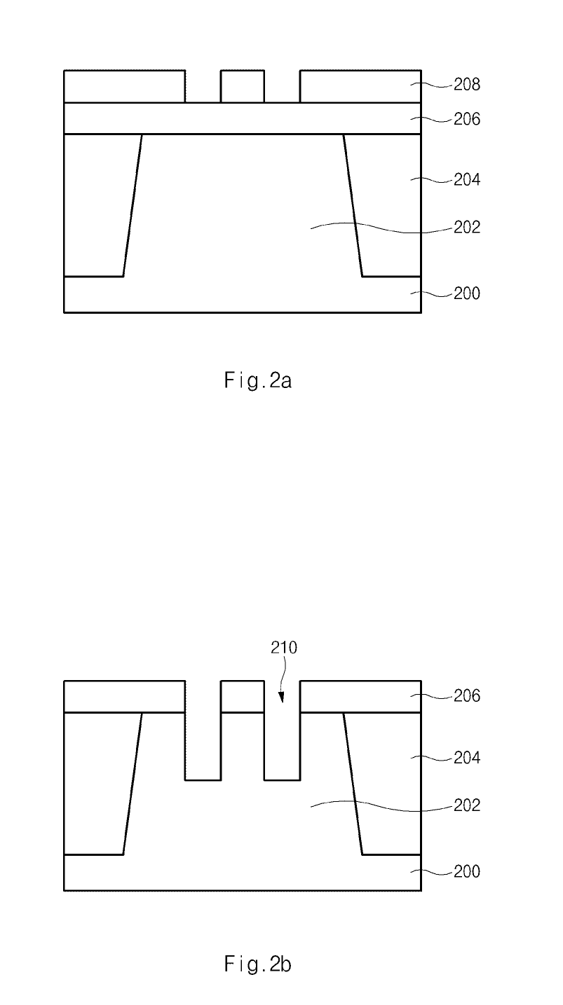

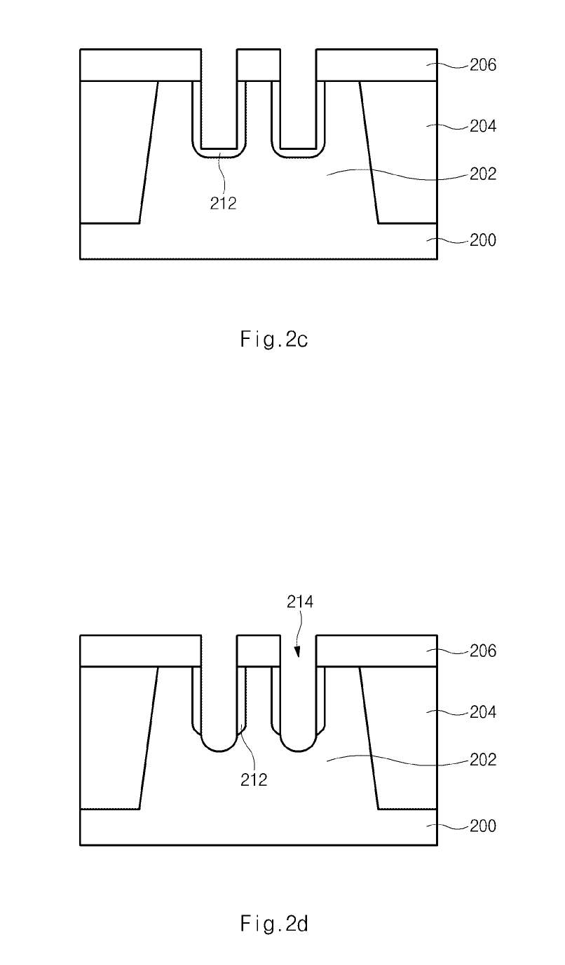

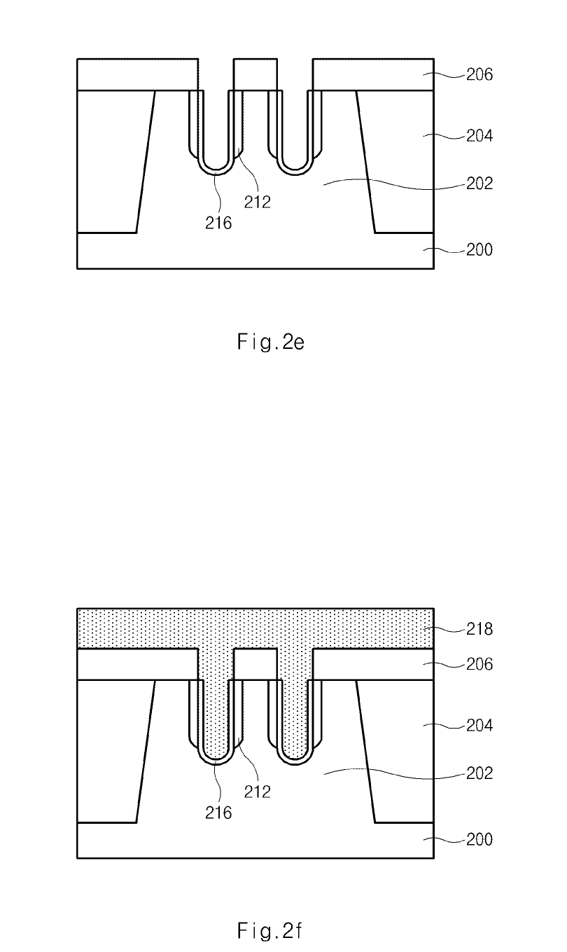

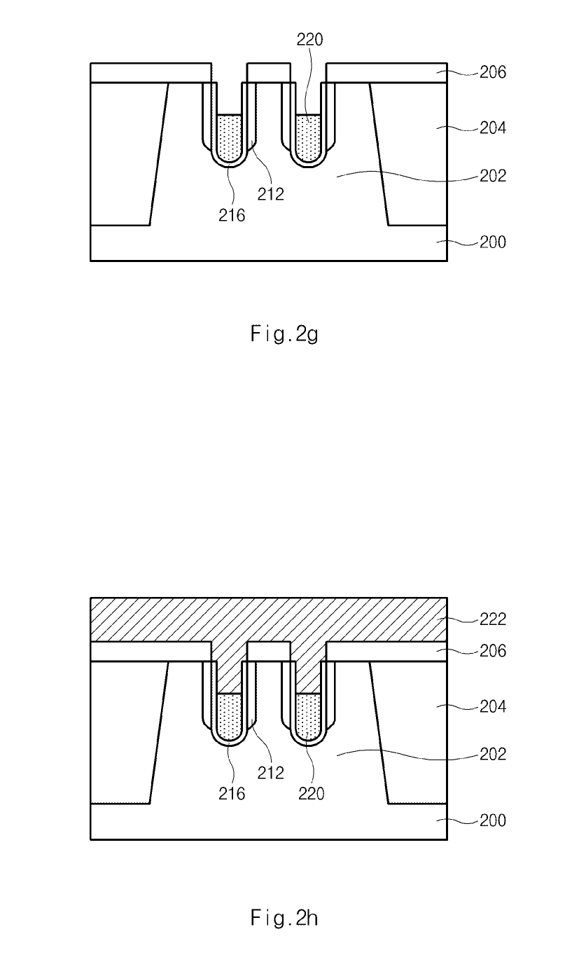

FIGS. 2a to 2h are cross-sectional views for explaining a fabricating method of a semiconductor memory device in accordance with a preferred embodiment of the present invention.

Referring to FIG. 2a, an element isolation film (or device isolation structure) 204 defining an active region 202 is formed on a semiconductor substrate 200. The element isolation film 204 can be formed though an STI process and is formed to a depth of about 3000 Å.

A hard mask film 206 is deposited on the active region 202 and the element isolation film 204, and a photoresist pattern 208 is formed on the hard mask film 206. The photoresist pattern 208 is patterned through an exposure process using a mask which defines a gate pattern.

Referring to FIG. 2b, after the hard mask film 206 is patterned using the photoresist pattern 208, a first recess 210 is formed by etching the exposed active region 202 using the patterned hard mask film. The first recess 210 is formed deeper than a source/drain contact junction region formed in the active region 202. Thereafter, the remaining photoresist pattern 208 is eliminated.

Referring to FIG. 2c, by oxidizing the active region 202 exposed by the first recess 210, an oxide film 212 is formed on a sidewall and a bottom of the first recess 210. Through an oxidation process, the oxide film 212 is formed in a thickness of about 100 to 200 Å.

The oxidation process for forming the oxide film 212 may use a dry oxidation, wet oxidation or radical oxidation method. Under a given temperature and process time, the oxide film 212 on the bottom of the first recess 210 is formed to be about 51 Å thick while the oxide film 212 on the sidewall is formed to be about 77 Å thick. However, in the case of the dry oxidation, under the same temperature and process conditions as above, the oxide film 212 on the bottom and on the sidewall of the first recess 210 are formed to be about 49 Å thick and 113 Å thick, respectively. Accordingly, the present embodiment uses the dry oxidation since it is preferable to form the oxide film 212 on the sidewall of the first recess 210 to be thicker than the oxide film on the bottom of the first recess 210 in certain implements.

Referring to FIG. 2d, a second recess 214 is formed by etching the bottom of the first recess 210 using the patterned hard mask film 206 as an etching mask. The oxide film 212 formed on the bottom of the first recess 210 is removed and only the oxide film 212 formed on the sidewall of the first recess 210 remains. In the present embodiment, the second recess 214 is formed to have a depth of about 1500 to 1700 Å. The depth can vary according to embodiments implemented.

Referring to FIG. 2e, a gate insulating film 216 is formed on the second recess 214. The gate insulating film 216 is thinner than the oxide film 212 in the present embodiment.

Referring to FIG. 2f, a conductive layer 218 filling the second recess 214 is formed.

Referring to FIG. 2g, an upper part of the conductive layer 218 is etched an etch-back process. The conductive layer 218 remaining in a lower part of the second recess 214 defines a buried gate 220. The buried gate 220 has a thickness of about 700 to 1000 Å in the present embodiment.

Referring to FIG. 2h, an insulating film 222 is formed on an upper part of the buried gate 220 and the hard mask film 206. The insulating film 222 completely fills the upper portion of the second recess 214 in the present embodiment.

As above-mentioned, according to the present invention, the oxide film and the gate insulating film are provided between the buried gate and the source/drain region. The oxide film reduces strength of electric field caused between a source/drain region and the buried gate, so that leakage current can be reduced.

For example, for the oxide film 212 formed through the above-mentioned oxidation process and having a thickness of is about 100 Å, the leakage current due to GIDL was measured to be about 0.014 fA, and data retention time (tREF) of a unit cell, which is a reference for judging refresh properties of a device, was measured to be about 650 ms. For the oxide film 212 having a thickness of about 75 Å, the leakage current due to GIDL was about 0.021 fA, and data retention time (tREF) was about 500 ms. Comparing the two cases according to the thickness of the oxide film 212, the data retention time (tREF) is increased about 30% when the thickness of the oxide film 212 is increased from about 75 Å to about 100 Å. Accordingly, in the preferred embodiment of the present invention, the oxide film 212 is formed to have a thickness of about 100 to 200 Å to improve the refresh properties of a device.

The manufacture method of the semiconductor device in accordance with one embodiment of present invention includes forming the semiconductor substrate including the active region and the element isolation film; a step of forming the first recess on the semiconductor substrate; a step of forming the oxide film on the sidewall of the first recess; a step of forming the second recess by etching the lower part of the first recess; and a step of forming the buried gate in the second recess. The semiconductor device formed according to this manufacturing method includes the semiconductor substrate including the active region and the element isolation film; the first recess formed on the active region; the oxide film formed on the sidewall of the first recess; the second recess more deeply extended from the first recess; and the buried gate formed within the second recess.

In accordance with an embodiment of the present invention, the oxide film is formed on the sidewall of the recess, and then the recess is filled with the conductive material. Therefore, the oxide film is positioned between the buried gate and the active region where the source/drain contact junction region is formed so as to reduce GIDL between the source/drain contact junction region and the gate, and thus improve the refresh properties of the semiconductor memory device.

Also, since the buried gate is formed after forming the oxide film on the sidewall of the recess, the active region can be prevented from being damaged by the etching process such as the etch-back process performed for forming the buried gate.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A manufacturing method of a semiconductor device, comprising:
providing a substrate including an active region and an element isolation film;
forming a first recess in the substrate in the active region, the first recess having a first depth;
forming an oxide film on a sidewall of the first recess;
etching a lower part of the first recess to form a second recess having a second depth that extends below the first depth, the second recess having a lower part and an upper part;
forming a gate electrode—in the lower part of the second recess; and
providing an insulating material over the gate and in the upper part of the second recess.

2. The manufacturing method according to claim 1, further comprising forming a gate insulating film over the oxide film within the second recess before forming the gate.

3. The manufacturing method according to claim 1, further comprising forming a source/drain region on the substrate at first and second sides of the recess, wherein a depth of the source and drain region is less than that of the oxide film.

4. The manufacturing method according to claim 3, wherein the gate electrode extends below the substrate by about 1500 to 1700 Å from the surface of the substrate and has a thickness of about 700 to 1000 Å.

5. The manufacturing method according to claim 1, wherein the forming the first recess on the substrate includes:
depositing a hard mask film on the substrate;
forming a photoresist pattern defining a gate region on the hard mask film;
patterning the hard mask film using the photoresist pattern; and
patterning the substrate using the patterned hard mask film as a mask.

6. The manufacturing method according to claim 1, wherein the forming the oxide film on the sidewall of the first recess includes a dry oxidation method for oxidizing the active region exposed by the first recess.

7. The manufacturing method according to claim 6, wherein the first oxide film is formed to a thickness of about 100 to 200 Å.

8. A semiconductor device, comprising:
a substrate including an active region defined by an element isolation film;
a recess formed within the active region of the substrate, the recess having a lower part and an upper part;
an oxide film formed on a sidewall of the recess;
a gate insulating film within the recess and provided over the oxide film;
a conductive layer provided in the lower part of the recess to define a gate electrode; and
an insulating layer provided over the conductive layer and in the upper part of the recess.

9. The semiconductor device according to claim 8, the conductive layer includes metal.

10. The semiconductor device according to claim 8, further comprising a source/drain region formed on the substrate at first and second sides of the recess, wherein the source/drain region is formed at a depth shallower than the oxide film.

11. The semiconductor device according to claim 8, wherein the oxide film is configured to prevent a leakage current from occurring between the gate electrode and the source/drain region.

12. The semiconductor device according to claim 8, wherein the gate electrode extends about 1500 to 1700 Å below an upper surface of the substrate and having a thickness of about 700 to 1000 Å.

13. The semiconductor device according to claim 12, wherein the element isolation film has a depth of about 3000 Å from an upper surface of the substrate.

14. The semiconductor device according to claim 8, wherein a thickness of the oxide film is about 100 to 200 Å.

15. The semiconductor device according to claim 14, wherein the oxide film is formed on the sidewalls of the first recess and is not provided on a bottom of the recess.
